(19) United States
(12) Patent Application Publication
(10) Pub. No.: US 2026/0026062 A1
(43) Pub. Date: Jan. 22, 2026

(54) WAFER, SEMICONDUCTOR DEVICE, AND METHOD FOR MANUFACTURING WAFER

(71) Applicant: KABUSHIKI KAISHA TOSHIBA, Tokyo (JP)

(72) Inventors: Hajime NAGO, Yokohama (JP); Jumpei TAJIMA, Mitaka (JP); Toshiki HIKOSAKA, Kawasaki (JP)

(73) Assignee: KABUSHIKI KAISHA TOSHIBA, Tokyo (JP)

(21) Appl. No.: 19/221,743

(22) Filed: May 29, 2025

(30) Foreign Application Priority Data
Jul. 22, 2024 (JP) 2024-117052

(51) Int. Cl. H10D 62/824; H10D 30/47

(52) U.S. Cl. CPC H10D 62/824; H10D 30/476

(57) ABSTRACT

According to one embodiment, a wafer includes a base, a first semiconductor layer including Alₓ₁Ga₁₋ₓ₁N (0≤x1<1), and a second semiconductor layer including Alₓ₂Ga₁₋ₓ₂N (x1<x2<1). The first semiconductor layer is between the base and the second semiconductor layer. The second semiconductor layer includes first to fourth regions. The first region is between the first semiconductor layer and the third region. The second region is between the first region and the third region. The fourth region is between the first semiconductor layer and the first region. A second Al composition ratio in the second region is lower than a third Al composition ratio in the third region. A first Al composition ratio in the first region is higher than the second Al composition ratio.

### CROSS-REFERENCE TO RELATED APPLICATIONS

This application is based upon and claims the benefit of priority from Japanese Patent Application No. 2024-117052, filed on Jul. 22, 2024; the entire contents of which are incorporated herein by reference.

### FIELD

Embodiments described herein relate generally to a wafer, a semiconductor device, and a method for manufacturing a wafer.

### BACKGROUND

For example, in semiconductor devices based on nitride semiconductors, improvements in the characteristics are desired.

### BRIEF DESCRIPTION OF THE DRAWINGS

FIG. 1 is a schematic cross-sectional view illustrating a wafer according to a first embodiment;

FIG. 2 is a graph illustrating a wafer according to the first embodiment;

FIG. 3 is a graphs illustrating wafer;

FIG. 4 is a graphs illustrating wafer;

FIG. 5 is a graphs illustrating wafer;

FIG. 6 is a graph illustrating the characteristics of the wafer;

FIGS. 7A to 7D are graphs illustrating the characteristics of the wafers;

FIG. 8 is a schematic cross-sectional view illustrating a wafer according to the first embodiment;

FIG. 9 is a schematic cross-sectional view illustrating a semiconductor device according to a second embodiment;

FIG. 10 is a schematic cross-sectional view illustrating a semiconductor device according to the second embodiment; and

FIGS. 11A and 11B are schematic diagrams illustrating a method for manufacturing a wafer according to the third embodiment.

### DETAILED DESCRIPTION

According to one embodiment, a wafer includes a base, a first semiconductor layer including Alₓ₁Ga₁₋ₓ₁N (0≤x1<1), and a second semiconductor layer including Alₓ₂Ga₁₋ₓ₂N (x1<x2<1). The first semiconductor layer is between the base and the second semiconductor layer in a first direction from the base to the second semiconductor layer. The second semiconductor layer includes a first region, a second region, a third region, and a fourth region. The first region is between the first semiconductor layer and the third region. The second region is between the first region and the third region. The fourth region is between the first semiconductor layer and the first region. A fourth Al composition ratio in the fourth region increases in a direction from the first semiconductor layer to the first region. A second Al composition ratio in the second region is lower than a third Al composition ratio in the third region. A first Al composition ratio in the first region is higher than the second Al composition ratio.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

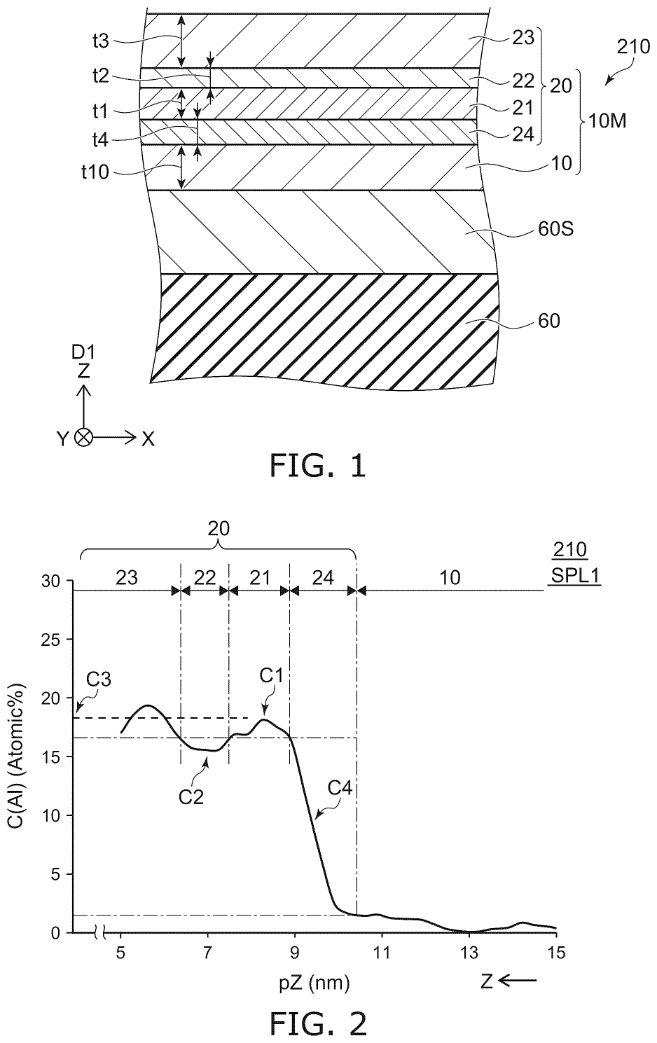

FIG. 1 is a schematic cross-sectional view illustrating a wafer according to a first embodiment.

FIG. 2 is a graph illustrating a wafer according to the first embodiment.

As shown in FIG. 1, a wafer 210 according to the embodiment includes a base 60, a first semiconductor layer 10, and a second semiconductor layer 20.

The first semiconductor layer 10 includes Alₓ₁Ga₁₋ₓ₁N (0≤x1<1). For example, the composition ratio x1 may be not less than 0 and not more than 0.13. The first semiconductor layer 10 may be a GaN layer.

The second semiconductor layer 20 includes Alₓ₂Ga₁₋ₓ₂N (x1<x2<1). The second semiconductor layer 20 may be an AlGaN layer. As described below, the second semiconductor layer 20 may change along the thickness direction. The average Al composition ratio x2 in the second semiconductor layer 20 may be, for example, exceeds 0.13 and less than 0.5.

The first semiconductor layer 10 is between the base 60 and the second semiconductor layer 20 in a first direction D1 from the base 60 to the second semiconductor layer 20. The first semiconductor layer 10 and the second semiconductor layer 20 are included in a semiconductor member 10M.

The first direction D1 is defined as a Z-axis direction. One direction perpendicular to the Z-axis direction is defined as an X-axis direction. A direction perpendicular to the Z-axis and X-axis directions is defined as a Y-axis direction. Each of the base 60, the first semiconductor layer 10, and the second semiconductor layer 20 is layered along the X-Y plane.

The second semiconductor layer 20 includes a first region 21, a second region 22, a third region 23, and a fourth region 24. The first region 21 is between the first semiconductor layer 10 and the third region 23. The second region 22 is between the first region 21 and the third region 23. The fourth region 24 is between the first semiconductor layer 10 and the first region 21.

FIG. 2 illustrates a results of EDX (Energy Dispersive X-ray Spectroscopy) analysis of a first sample SPL1 corresponding to the wafer 210 according to the embodiment. In FIG. 2, the horizontal axis is the position pZ in the Z-axis direction. The vertical axis is the Al concentration C(Al). The Al concentration C(Al) corresponds to the Al composition ratio.

As shown in FIG. 2, a fourth Al composition ratio C4 in the fourth region 24 increases in a direction from the first semiconductor layer 10 to the first region 21. A second Al composition ratio C2 in the second region 22 is lower than a third Al composition ratio C3 in the third region 23. A first Al composition ratio C1 in the first region 21 is higher than the second Al composition ratio C2.

For example, it is preferable that the Al composition ratio changes appropriately sharply between the first semiconductor layer 10, which has a low Al composition ratio, and the second semiconductor layer 20, which has a high Al composition ratio. Thereby, for example, an appropriate amount of carriers can be generated. In a semiconductor device using the wafer 210, high mobility can be obtained. Here, if the composition ratio changes too sharply, there is a possibility that the continuity of crystallinity will be adversely affected due to differences in lattice length, etc.

For example, the third region 23 is a region in which the Al composition ratio is substantially constant. In the embodiment, the profile of the Al composition ratio in the region between the first semiconductor layer 10 and the third region 23 is appropriately controlled. Thereby, the Al composition ratio in the region between the first semiconductor layer 10 and the second semiconductor layer 20 can be changed appropriately and steeply.

In the wafer 210, the first region 21 is provided in which the Al composition ratio is locally high. Thereby, a steep change can be obtained. Furthermore, the second region 22 is provided in which the Al composition ratio is locally low. Thereby, it is suppressed that the first Al composition ratio C1 in the first region 21, where the Al composition ratio is locally high, becomes excessively high. For example, even in a situation in which the concentration of Al in the position corresponding to the first region 21 becomes excessively high, the excess Al can move into the second region 22 by diffusion or the like. As a result, the first Al composition ratio C1 in the first region 21 is unlikely to become excessively high. The adverse effects of an excessively steep change can be suppressed.

Furthermore, as described below, it has been found that if the first Al composition ratio C1 in the first region 21 is excessively high, the electrical resistance between the first semiconductor layer 10 and the second semiconductor layer 20 (e.g., the third region 23) increases. By providing the second region 22, in which the Al composition ratio is locally low, the first Al composition ratio C1 being excessively high is suppressed, and low electrical resistance can be maintained.

With the wafer 210 according to the embodiment, for example, high mobility can be obtained. High crystallinity can be obtained. For example, low electrical resistance can be obtained. According to the embodiment, it is possible to provide a wafer and a semiconductor device that can improve characteristics.

In the first sample SPL1, the electron mobility is 2047 cm²/Vs. The electrical resistance (contact resistance) is 0.563 Ωmm. High electron mobility and low contact resistance are obtained.

In FIG. 2, for example, the Al composition ratio in the third region 23 may be substantially constant in the Z-axis direction (first direction D1). The Al composition ratio in the third region 23 may vary in the Z-axis direction due to non-uniformity in the sample or characteristics of the analysis method. The third Al composition ratio C3 in the third region 23 may be the average value of the Al composition ratio in the first direction D1 in the third region 23. In FIG. 2, the average value of the Al composition ratio in the first direction D1 in the third region 23 is indicated by a dashed line as the third Al composition ratio C3. The Al composition ratio in the third region 23 may vary within a range of ±10% of the average value.

In the embodiment, for example, a region in which an Al composition ratio less than 0.9 times the third Al composition ratio C3 (average value) is obtained may correspond to the second region 22. For example, the second Al composition ratio C2 is less than 0.9 times the third Al composition ratio C3 (average value).

In the embodiment, for example, a region where an Al composition ratio of 0.9 times or more the third Al composition ratio C3 (average value) is obtained may correspond to the first region 21. For example, the first Al composition ratio C1 is 0.9 times or more the third Al composition ratio C3 (average value). The first Al composition ratio C1 may be 2 times or less the third Al composition ratio C3 (average value). The first Al composition ratio C1 may be 1.2 times or less the third Al composition ratio C3 (average value).

For example, the fourth region 24 may correspond to a region in which the Al composition ratio varies from 0.1 to 0.9 times the third Al composition ratio C3 (average value). For example, the fourth Al composition ratio C4 may vary between 0.1 times the third Al composition ratio C3 (average value) and 0.9 times the third Al composition ratio.

The first region 21 contacts the fourth region 24 and the second region 22. The second region 22 contacts the first region 21 and the third region 23. Due to the above definition, a part of the second semiconductor layer 20 may be present between the fourth region 24 and the first semiconductor layer 10. In this part of the second semiconductor layer 20, the Al composition ratio changes between 0.1 times the third Al composition ratio C3 (average value) and the Al composition ratio in the first semiconductor layer 10. The second semiconductor layer 20 may contact the first semiconductor layer 10.

As shown in FIG. 1, a first thickness t1 in the first direction D1 of the first region 21 may be thinner than a third thickness t3 in the first direction D1 of the third region 23. A second thickness t2 in the first direction D1 of the second region 22 may be thinner than the third thickness t3.

A fourth thickness t4 in the first direction D1 of the fourth region 24 may be equal to or less than the sum of the first thickness t1 and the second thickness t2. A steep change in Al is obtained.

The fourth thickness t4 may be, for example, 2.5 nm or less. The first thickness t1 may be, for example, not less than 1 nm and not more than 2 nm. The second thickness t2 may be, for example, not less than 0.5 nm and not more than 2 nm. The third thickness t3 may be, for example, not less than 5 nm and not more than 50 nm.

The first Al composition ratio C1 may be, for example, not less than 0.16 and not more than 0.48. The second Al composition ratio C2 may be, for example, not less than 0.14 and not more than 0.2. The third Al composition ratio C3 may be, for example, not less than 0.16 and not more than 0.3.

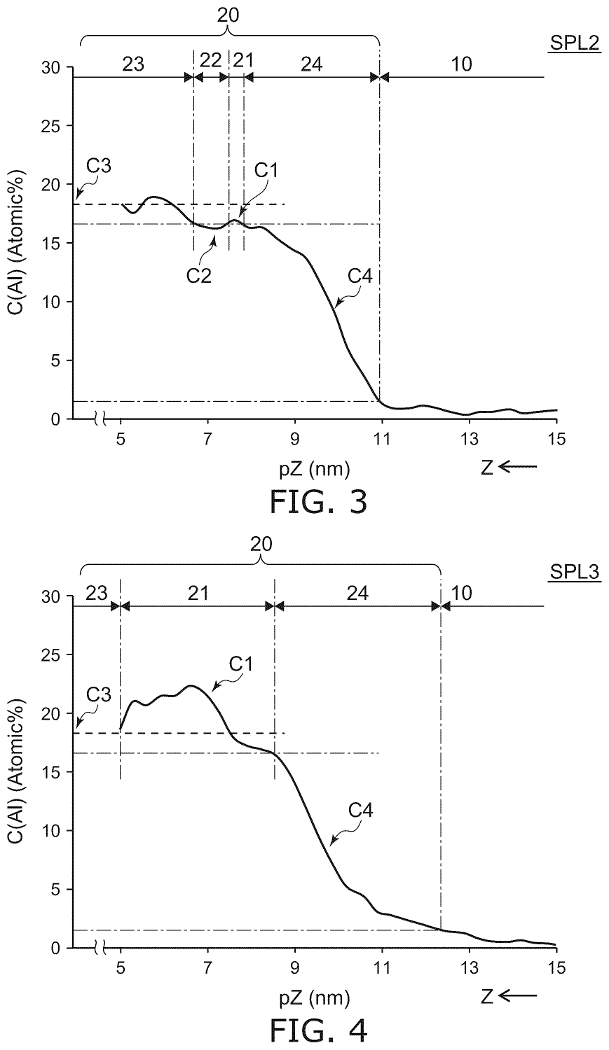

FIGS. 3 to 5 are graphs illustrating wafers.

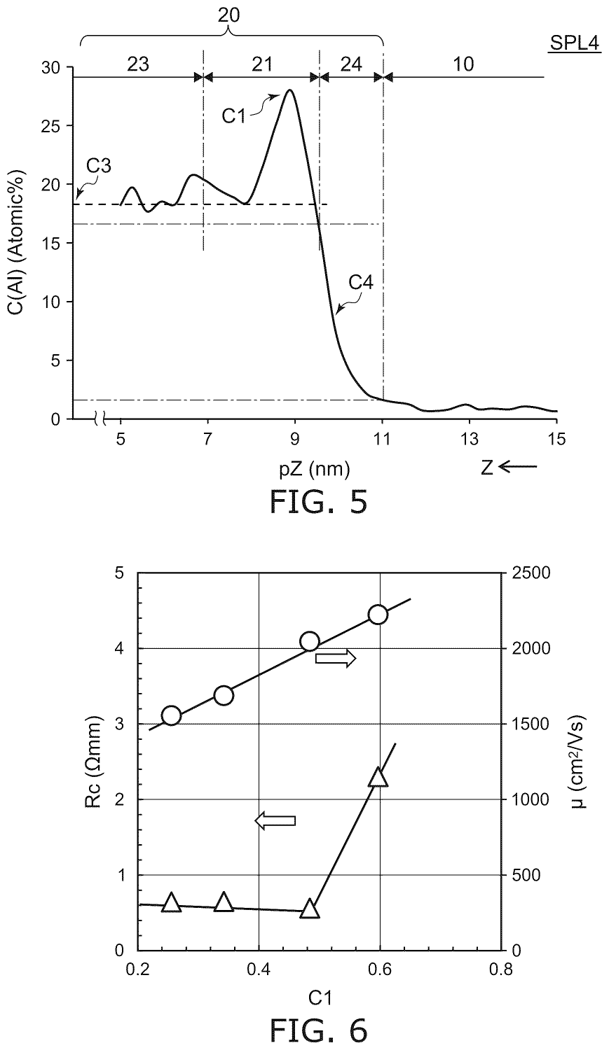

FIG. 3 corresponds to a second sample SPL2. FIG. 4 corresponds to a third sample SPL3. FIG. 5 corresponds to a fourth sample SPL4. These samples correspond to reference examples. The horizontal axis of these figures is the position pZ in the Z-axis direction. The vertical axis is the Al concentration C(Al).

As shown in FIG. 3, the second sample SPL2 has the first region 21, the second region 22, the third region 23, and the fourth region 24. In the second sample SPL2, the first thickness t1 of the first region 21 is about 0.3 nm. The fourth thickness t4 of the fourth region 24 is about 3 nm, and the Al concentration C(Al) changes gradually. In the second sample SPL2, the electron mobility is 1555 cm²/Vs. The electrical resistance (contact resistance) is 0.645 Ωmm. Compared to the first sample SPL1, the second sample SPL2 has a lower electron mobility and a higher contact resistance.

As shown in FIG. 4, the second region 22 does not exist in the third sample SPL3. The Al concentration C(Al) changes gradually. In the third sample SPL3, the electron mobility is 1687 cm²/Vs. The electrical resistance (contact resistance) is 0.651 Ωmm. In the third sample SPL3, the electron mobility is lower and the contact resistance is higher than those in the first sample SPL1.

As shown in FIG. 5, the second region 22 does not exist in the fourth sample SPL4. The Al concentration C(Al) changes abruptly. The first Al composition ratio C1 is excessively high in the fourth sample SPL4. The electron mobility is 2223 cm²/Vs in the fourth sample SPL4. The electrical resistance (contact resistance) is 2.303 Ωmm. Compared to the first sample SPL1, the fourth sample SPL4 has a high electron mobility, but an extremely high contact resistance. The extremely high contact resistance is thought to be due to the first Al composition ratio C1 being excessively high.

FIG. 6 is a graph illustrating the characteristics of the wafer.

FIG. 6 shows the characteristics of the first sample SPL1, the second sample SPL2, the third sample SPL3, and the fourth sample SPL4. The horizontal axis of FIG. 6 is the first Al composition ratio C1. The left vertical axis is the contact resistance Rc. The right horizontal axis is the electron mobility u.

As shown in FIG. 6, as the first Al composition ratio C1 increases, the electron mobility u increases. In the region where the first Al composition ratio C1 is 0.48 or less, as the first Al composition ratio C1 increases, the contact resistance Rc decreases slightly. When the first Al composition ratio C1 becomes 0.5 or more, the contact resistance Rc increases significantly.

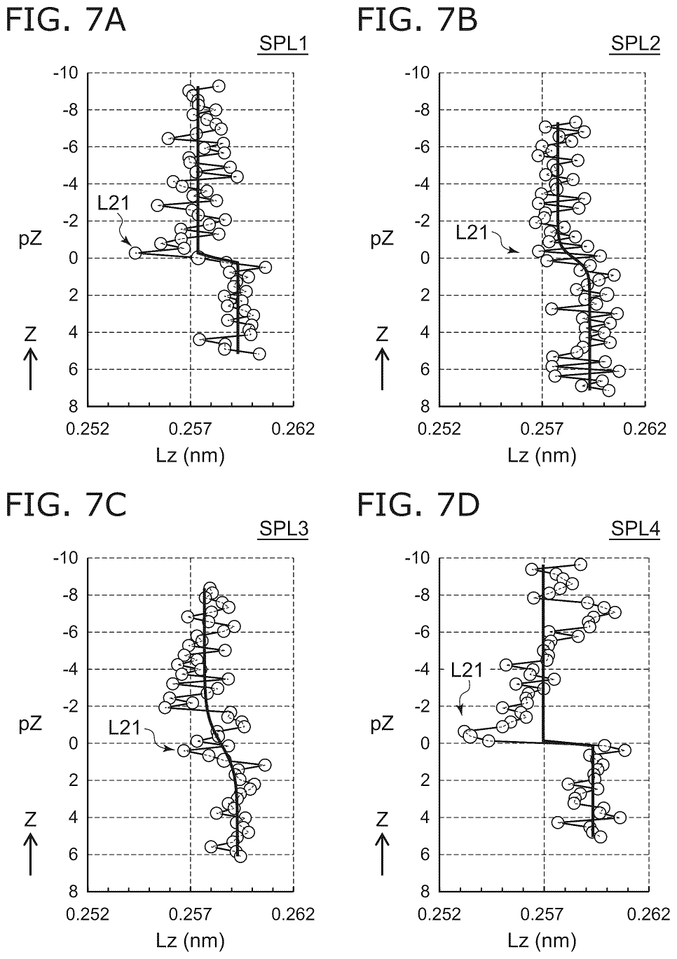

FIGS. 7A to 7D are graphs illustrating the characteristics of the wafers.

These figures correspond to the first sample SPL1, the second sample SPL2, the third sample SPL3, and the fourth sample SPL4, respectively. The horizontal axis of these figures is the lattice plane spacing Lz in the Z-axis direction (first direction D1). The vertical axis is the position pZ in the Z-axis direction. The lattice plane spacing Lz is derived based on information about the positions of atoms obtained from a TEM (transmission electron microscope) image of the sample.

As shown in FIG. 7A, in the first sample SPL1, the first lattice plane spacing L21 in the first direction D1 in the first region 21 is approximately 0.254 nm.

As shown in FIG. 7B, in the second sample SPL2, the first lattice plane spacing L21 is approximately 0.2568 nm.

As shown in FIG. 7C, in the third sample SPL3, the first lattice plane spacing L21 is approximately 0.2566 nm.

As shown in FIG. 7D, in the fourth sample SPL4, the first lattice plane spacing L21 is approximately 0.253 nm.

In the embodiment, the first lattice plane spacing L21 in the first direction D1 in the first region 21 is preferably not less than 0.254 nm and not more than 0.256 nm. Thereby, high electron mobility and low contact resistance can be obtained.

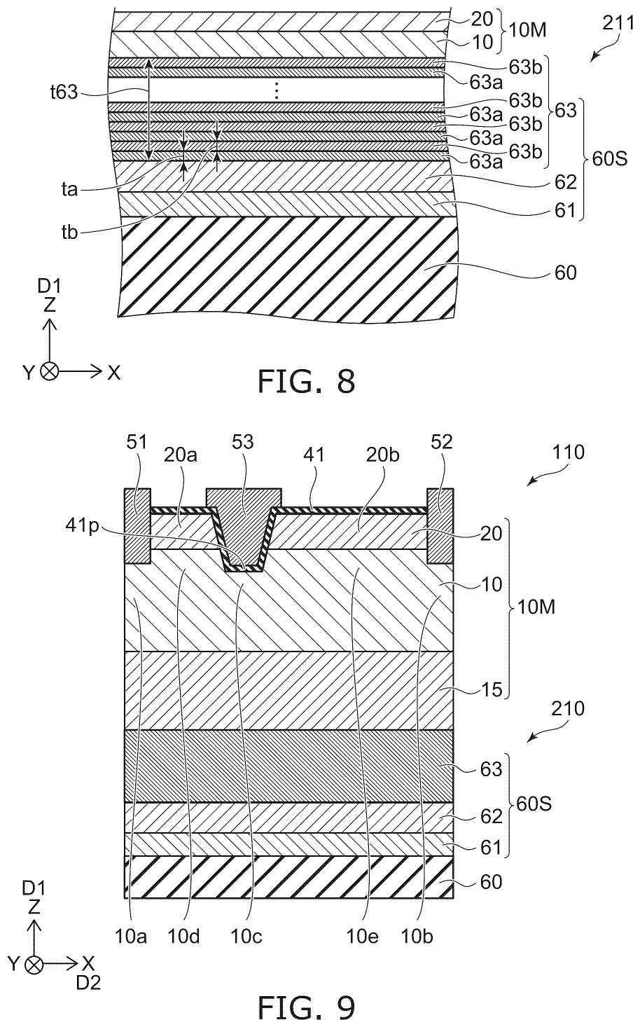

FIG. 8 is a schematic cross-sectional view illustrating a wafer according to the first embodiment.

As shown in FIG. 8, a wafer 211 according to the embodiment includes a nitride member 60S. Except for this, the configuration of the wafer 211 may be the same as the configuration of the wafer 210.

The nitride member 60S is provided between the base 60 and the first semiconductor layer 10. The nitride member 60S includes a first nitride layer 61 including Al_{z1}Ga_{1-z1}N (0<z1≤1) and a second nitride layer 62 including Al_{z2}Ga_{1-z2}N (0<z2<z1). The first nitride layer 61 is between the base 60 and the first semiconductor layer 10. The second nitride layer 62 is between the first nitride layer 61 and the first semiconductor layer 10.

The base 60 may be, for example, a silicon substrate. The base 60 may be, for example, a GaN substrate or a SiC substrate. The first nitride layer 61 may be, for example, an AlN layer. The second nitride layer 62 may be, for example, an AlGaN layer. These nitride layers may be, for example, at least a part of a buffer layer.

The nitride member 60S may further include a stacked body 63 including Al, Ga, and N. The stacked body 63 is between the second nitride layer 62 and the first semiconductor layer 10. The stacked body 63 includes a plurality of first nitride films 63a and a plurality of second nitride films 63b. One of the plurality of first nitride films 63a is between one of the plurality of second nitride films 63b and another one of the plurality of second nitride films 63b. One of the plurality of second nitride films 63b is between one of the plurality of first nitride films 63a and another one of the plurality of first nitride films 63a. The composition ratio of Al in the plurality of first nitride films 63a is different from the composition ratio of Al in the plurality of second nitride films 63b. The stacked body 63 may be, for example, a superlattice layer.

### Second Embodiment

FIG. 9 is a schematic cross-sectional view illustrating a semiconductor device according to a second embodiment.

As shown in FIG. 9, a semiconductor device 110 according to the embodiment includes a wafer (e.g., wafer 210) according to the first embodiment, a first electrode 51, a second electrode 52, and a third electrode 53.

A second direction D2 from the first electrode 51 to the second electrode 52 crosses the first direction D1. The second direction D2 may be, for example, the X-axis direction. A position of the third electrode 53 in the second direction D2 is between a position of the first electrode 51 in the second direction D2 and a position of the second electrode 52 in the second direction D2.

The second semiconductor layer 20 includes a first semiconductor portion 20a and a second semiconductor portion 20b. A direction from the first semiconductor portion 20a to the second semiconductor portion 20b is along the second direction D2. The first electrode 51 is electrically connected to the first semiconductor portion 20a. The second electrode 52 is electrically connected to the second semiconductor portion 20b.

Current flowing between the first electrode 51 and the second electrode 52 is controlled by a potential of the third electrode 53. The potential of the third electrode 53 may be, for example, a potential based on a potential of the first electrode 51. The first electrode 51 functions as, for example, a source electrode. The second electrode 52 functions as a drain electrode. The third electrode 53 functions as a gate electrode. The semiconductor device 110 is, for example, a transistor.

The first semiconductor layer 10 includes a region facing the second semiconductor layer 20. A carrier region is formed in this region. The carrier region is, for example, a two-dimensional electron gas. The semiconductor device 110 is, for example, a HEMT (High Electron Mobility Transistor).

In the semiconductor device 110, high electron mobility and low contact resistance are obtained. For example, low on-resistance is obtained.

As shown in FIG. 9, in this example, at least a part of the third electrode 53 is provided between the first semiconductor portion 20a and the second semiconductor portion 20b in the second direction D2. The third electrode 53 is, for example, a recessed gate electrode. For example, normally-off characteristics are obtained. At least a part of the third electrode 53 may be provided between a part of the first semiconductor layer 10 and another part of the first semiconductor layer 10 in the second direction D2.

For example, the first semiconductor layer 10 includes a first partial region 10a, a second partial region 10b, a third partial region 10c, a fourth partial region 10d, and a fifth partial region 10e. A direction from the first partial region 10a to the first electrode 51 is along the first direction D1. A direction from the second partial region 10b to the second electrode 52 is along the first direction D1. A direction from the third partial region 10c to the third electrode 53 is along the first direction D1.

A position of the fourth partial region 10d in the second direction D2 is between a position of the first partial region 10a in the second direction D2 and a position of the third partial region 10c in the second direction D2. A position of the fifth partial region 10e in the second direction D2 is between the position of the third partial region 10c in the second direction D2 and the position of the second partial region 10b in the second direction D2.

A direction from the fourth partial region 10d to the first semiconductor portion 20a is along the first direction D1. A direction from the fifth partial region 10e to the second semiconductor portion 20b is along the first direction D1. In this example, a part of the third electrode 53 is between the fourth partial region 10d and the fifth partial region 10e in the second direction D2. A high threshold voltage is obtained. For example, stable normally-off operation is obtained.

As shown in FIG. 9, the semiconductor device 110 may further include a first insulating member 41. The first insulating member 41 includes a first insulating portion 41p provided between the third electrode 53 and the semiconductor member 10M. The first insulating portion 41p functions as, for example, a gate insulating film.

As shown in FIG. 9, the semiconductor member 10M may further include an intermediate nitride layer 15. The intermediate nitride layer 15 is, for example, a GaN layer. The carbon concentration in the intermediate nitride layer 15 is higher than the carbon concentration in the first semiconductor layer 10. The intermediate nitride layer 15 is provided as necessary, and may be omitted.

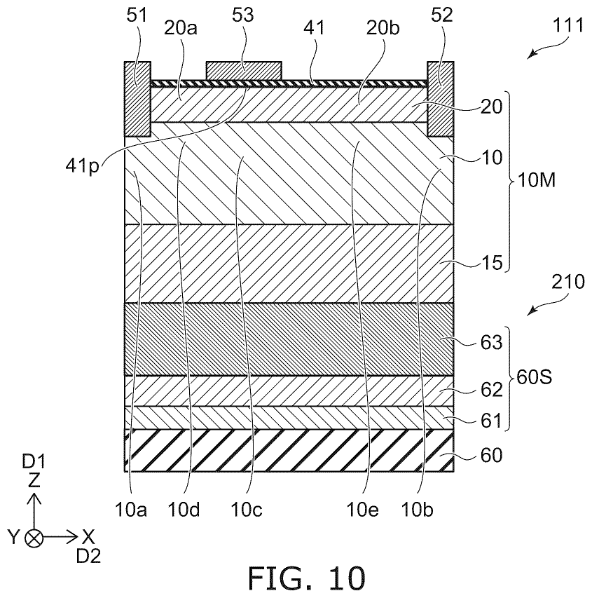

FIG. 10 is a schematic cross-sectional view illustrating a semiconductor device according to the second embodiment.

As shown in FIG. 10, a semiconductor device 111 according to the embodiment includes a wafer (e.g., wafer 210) according to the first embodiment, the first electrode 51, the second electrode 52, and the third electrode 53. In the semiconductor device 111, the third electrode 53 does not overlap the second semiconductor layer 20 in the second direction D2. Except for this, the configuration of the semiconductor device 111 may be the same as that of the semiconductor device 110.

The semiconductor device 111 can, for example, operate in a normally-on state. In the semiconductor device 111, the first insulating member 41 may be omitted. For example, the semiconductor device 111 may be used as a high-frequency switching element.

### Third Embodiment

The third embodiment relates to a method for manufacturing a wafer.

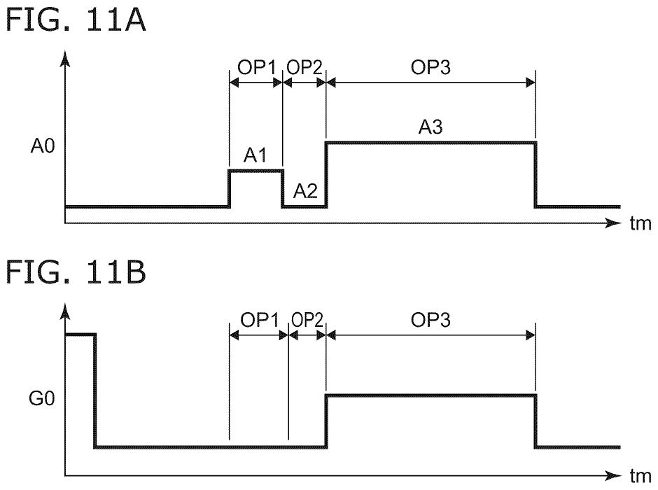

FIGS. 11A and 11B are schematic diagrams illustrating a method for manufacturing a wafer according to the third embodiment.

In these figures, the horizontal axis is time tm. The vertical axis in FIG. 11A is the supply amount A0 of the first source gas including Al. The vertical axis in FIG. 11B is the supply amount G0 of the second source gas including Ga.

As shown in FIG. 11A, a first process OP1 is performed. In the first process OP1, a first semiconductor layer 10 including Alₓ₁Ga₁₋ₓ₁N (0≤x1<1) is subjected to the first process OP1 using the first source gas including Al. In the first process OP1, the first source gas is supplied at a first supply amount A1. In the first process OP1, a third source gas including N may be supplied and a heat treatment may be performed.

As shown in FIG. 11B, in the first process OP1, the supply amount G0 of the second source gas may be small. In the first process OP1, the second source gas may not be supplied. For example, the fourth region 24 and at least a part of the first region 21 may be formed by the first process OP1.

As shown in FIG. 11A, after the first process OP1, a second process OP2 is performed. In the second process OP2, the first source gas is not used. Alternatively, the second supply amount A2 of the first source gas in the second process OP2 is smaller than the first supply amount A1. In the second process OP2, the third source gas including N may be supplied and the heat treatment may be performed.

As shown in FIG. 11B, in the second process OP2, the supply amount G0 of the second source gas may be small. In the second process OP2, the second source gas may not be supplied. By the second process OP2, for example, the second region 22 is formed.

As shown in FIG. 11A, after the second process OP2, a third process OP3 is performed. In the third process OP3, a process is performed using a first source gas and a second source gas including Ga. Thereby, a part of the second semiconductor layer 20 including Alₓ₂Ga₁₋ₓ₂N (x1<x2<1) is formed. For example, the third region 23 may be formed by the third process OP3.

The third supply amount A3 of the first source gas in the third process OP3 may be larger than the first supply amount A1. This makes it easier to obtain the third region 23 being uniform.

According to the method for manufacturing the wafer in the embodiment, the second region 22 having a locally low Al composition ratio can be stably formed. According to the embodiment, a method for manufacturing a wafer capable of improving characteristics is provided.

In the embodiment, information regarding the shape of the nitride region is obtained, for example, from an electron microscope image. Information regarding the composition and element concentration is obtained, for example, from EDX (Energy Dispersive X-ray Spectroscopy) or SIMS (Secondary Ion Mass Spectrometry). Information regarding the composition may be obtained, for example, from reciprocal space mapping.

The embodiments may include the following Technical proposals:

### Technical Proposal 1

A wafer, comprising:
a base;
a first semiconductor layer including Alₓ₁Ga₁₋ₓ₁N (0≤x1<1); and
a second semiconductor layer including Alₓ₂Ga₁₋ₓ₂N (x1<x2<1),
the first semiconductor layer being between the base and the second semiconductor layer in a first direction from the base to the second semiconductor layer,
the second semiconductor layer including a first region, a second region, a third region, and a fourth region,
the first region being between the first semiconductor layer and the third region,
the second region being between the first region and the third region,
the fourth region being between the first semiconductor layer and the first region,
a fourth Al composition ratio in the fourth region increasing in a direction from the first semiconductor layer to the first region,
a second Al composition ratio in the second region being lower than a third Al composition ratio in the third region, and
a first Al composition ratio in the first region being higher than the second Al composition ratio.

### Technical Proposal 2

The wafer according to Technical proposal 1, wherein
the third Al composition ratio is an average value of an Al composition ratio in the third region in the first direction,
the second Al composition ratio is less than 0.9 times the third Al composition ratio, and
the first Al composition ratio is 0.9 times or more the third Al composition ratio.

### Technical Proposal 3

The wafer according to Technical proposal 2, wherein
the first Al composition ratio is not more than 2 times the third Al composition ratio.

### Technical Proposal 4

The wafer according to Technical proposal 2, wherein
the first Al composition ratio is not more than 1.2 times the third Al composition ratio.

### Technical Proposal 5

The wafer according to Technical proposal 2, wherein
the fourth Al composition ratio varies between 0.1 times the third Al composition ratio and 0.9 times the third Al composition ratio.

### Technical Proposal 6

The wafer according to any one of Technical proposals 1-5, wherein
a first thickness of the first region in the first direction is thinner than a third thickness of the third region in the first direction, and
a second thickness of the second region in the first direction is thinner than the third thickness.

### Technical Proposal 7

The wafer according to Technical proposal 6, wherein
a fourth thickness of the fourth region in the first direction is equal to or smaller than a sum of the first thickness and the second thickness.

### Technical Proposal 8

The wafer according to Technical proposal 7, wherein
the fourth thickness is less than or equal to 2.5 nm.

### Technical Proposal 9

The wafer according to any one of Technical proposals 6-8, wherein
the first thickness is not less than 1 nm and not more than 2 nm, and
the second thickness is not less than 0.5 nm and not more than 2 nm.

### Technical Proposal 10

The wafer according to any one of Technical proposals 1-9, wherein
the first region is in contact with the fourth region and the second region, and
the second region is in contact with the first region and the third region.

### Technical Proposal 11

The wafer according to any one of Technical proposals 1-10, wherein
the first Al composition ratio is not less than 0.16 and not more than 0.48.

### Technical Proposal 12

The wafer according to Technical proposal 11, wherein the second Al composition ratio is not less than 0.14 and not more than 0.2.

### Technical Proposal 13

The wafer according to Technical proposal 12, wherein
the third Al composition ratio is not less than 0.16 and not more than 0.3.

### Technical Proposal 14

The wafer according to any one of Technical proposals 1-13, wherein
the first lattice plane spacing in the first direction in the first region is not less than 0.254 nm and not more than 0.256 nm.

### Technical Proposal 15

The wafer according to any one of Technical proposals 1-14, further comprising:
a nitride member provided between the base and the first semiconductor layer,
the nitride member including:
   a first nitride layer including Al_{z1}Ga_{1-z1}N (0<z1≤1); and
   a second nitride layer including Al_{z2}Ga_{1-z2}N (0<z2<z1),
the first nitride layer being between the base and the first semiconductor layer, and
the second nitride layer being between the first nitride layer and the first semiconductor layer.

### Technical Proposal 16

The wafer according to Technical proposal 15, wherein
the nitride member further includes a stacked body including Al, Ga, and N,
the stacked body is between the second nitride layer and the first semiconductor layer,
the stacked body includes a plurality of first nitride films and a plurality of second nitride films,
one of the plurality of first nitride films is between one of the plurality of second nitride films and another one of the plurality of second nitride films,
the one of the plurality of second nitride films is between the one of the plurality of first nitride films and another one of the plurality of first nitride films, and
an Al composition ratio in the plurality of first nitride films is different from an Al composition ratio in the plurality of second nitride films.

### Technical Proposal 17

A semiconductor device, comprising:
the wafer according to any one of Technical proposals 1 to 16;
a first electrode;
a second electrode; and
a third electrode,
a second direction from the first electrode to the second electrode crossing the first direction,
a position of the third electrode in the second direction being between a position of the first electrode in the second direction and a position of the second electrode in the second direction,
the second semiconductor layer includes a first semiconductor portion and a second semiconductor portion,
a direction from the first semiconductor portion to the second semiconductor portion is along the second direction,
the first electrode being electrically connected to the first semiconductor portion,
the second electrode being electrically connected to the second semiconductor portion.

### Technical Proposal 18

The semiconductor device according to Technical proposal 17, wherein
at least a part of the third electrode is between the first semiconductor portion and the second semiconductor portion in the second direction.

### Technical Proposal 19

A method for manufacturing a wafer, comprising:
performing a first process on a first semiconductor layer including Alₓ₁Ga₁₋ₓ₁N (0≤x1<1) using a first source gas including Al, the first source gas being supplied at a first supply amount in the first process;
performing a second process after the first process, the first source gas being not used in the second process, or a second supply amount of the first source gas in the second process being smaller than the first supply amount; and
performing a third process using the first source gas and a second source gas to form a part of a second semiconductor layer after the second process, the second source gas including Ga, and the second semiconductor layer including Alₓ₂Ga₁₋ₓ₂N (x1<x2<1).

### Technical Proposal 20

The method for manufacturing the wafer according to Technical proposal 19, wherein
a third supply amount of the first source gas in the third process is greater than the first supply amount.

According to the embodiment, it is possible to provide a wafer, a semiconductor device, and a method for manufacturing a wafer that can improve characteristics.

In this specification, “an electrically connected state” includes a state in which multiple conductors are in physical contact with each other and a current flows between the multiple conductors. “An electrically connected state” includes a state in which a conductor is inserted between multiple conductors and a current flows between the multiple conductors.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the wafer and the semiconductor devices such as bases, semiconductor layers, electrodes, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all wafers, all semiconductor devices, and all methods for manufacturing wafers practicable by an appropriate design modification by one skilled in the art based on the wafers, the semiconductor devices, and the methods for manufacturing wafers described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A wafer, comprising:
a base;
a first semiconductor layer including Alₓ₁Ga₁₋ₓ₁N (0≤x1<1; and
a second semiconductor layer including Alₓ₂Ga₁₋ₓ₂N (x1<×2<1),
the first semiconductor layer being between the base and the second semiconductor layer in a first direction from the base to the second semiconductor layer,
the second semiconductor layer including a first region, a second region, a third region, and a fourth region,
the first region being between the first semiconductor layer and the third region,
the second region being between the first region and the third region,
the fourth region being between the first semiconductor layer and the first region,
a fourth Al composition ratio in the fourth region increasing in a direction from the first semiconductor layer to the first region,
a second Al composition ratio in the second region being lower than a third Al composition ratio in the third region, and
a first Al composition ratio in the first region being higher than the second Al composition ratio.

2. The wafer according to claim 1, wherein
the third Al composition ratio is an average value of an Al composition ratio in the third region in the first direction,
the second Al composition ratio is less than 0.9 times the third Al composition ratio, and
the first Al composition ratio is 0.9 times or more the third Al composition ratio.

3. The wafer according to claim 2, wherein
the first Al composition ratio is not more than 2 times the third Al composition ratio.

4. The wafer according to claim 3, wherein
the first Al composition ratio is not more than 1.2 times the third Al composition ratio.

5. The wafer according to claim 2, wherein
the fourth Al composition ratio varies between 0.1 times the third Al composition ratio and 0.9 times the third Al composition ratio.

6. The wafer according to claim 1, wherein
a first thickness of the first region in the first direction is thinner than a third thickness of the third region in the first direction, and
a second thickness of the second region in the first direction is thinner than the third thickness.

7. The wafer according to claim 6, wherein
a fourth thickness of the fourth region in the first direction is equal to or smaller than a sum of the first thickness and the second thickness.

8. The wafer according to claim 7, wherein
the fourth thickness is less than or equal to 2.5 nm.

9. The wafer according to claim 6, wherein
the first thickness is not less than 1 nm and not more than 2 nm, and
the second thickness is not less than 0.5 nm and not more than 2 nm.

10. The wafer according to claim 1, wherein
the first region is in contact with the fourth region and the second region, and
the second region is in contact with the first region and the third region.

11. The wafer according to claim 1, wherein
the first Al composition ratio is not less than 0.16 and not more than 0.48.

12. The wafer according to claim 11, wherein
the second Al composition ratio is not less than 0.14 and not more than 0.2.

13. The wafer according to claim 12, wherein
the third Al composition ratio is not less than 0.16 and not more than 0.3.

14. The wafer according to claim 1, wherein
the first lattice plane spacing in the first direction in the first region is not less than 0.254 nm and not more than 0.256 nm.

15. The wafer according to claim 1, further comprising:
a nitride member provided between the base and the first semiconductor layer,
the nitride member including:
a first nitride layer including Al_{z1}Ga_{1-z1}N (0<z1≤1); and
a second nitride layer including Al_{z2}Ga_{1-z2}N (0<z2<z1),
the first nitride layer being between the base and the first semiconductor layer, and
the second nitride layer being between the first nitride layer and the first semiconductor layer.

16. The wafer according to claim 15, wherein
the nitride member further includes a stacked body including Al, Ga, and N,
the stacked body is between the second nitride layer and the first semiconductor layer,
the stacked body includes a plurality of first nitride films and a plurality of second nitride films,
one of the plurality of first nitride films is between one of the plurality of second nitride films and another one of the plurality of second nitride films,
the one of the plurality of second nitride films is between the one of the plurality of first nitride films and another one of the plurality of first nitride films, and
an Al composition ratio in the plurality of first nitride films is different from an Al composition ratio in the plurality of second nitride films.

17. A semiconductor device, comprising:
the wafer according to claim 1;
a first electrode;
a second electrode; and
a third electrode,
a second direction from the first electrode to the second electrode crossing the first direction,
a position of the third electrode in the second direction being between a position of the first electrode in the second direction and a position of the second electrode in the second direction,
the second semiconductor layer includes a first semiconductor portion and a second semiconductor portion,
a direction from the first semiconductor portion to the second semiconductor portion is along the second direction,
the first electrode being electrically connected to the first semiconductor portion,
the second electrode being electrically connected to the second semiconductor portion.

18. The semiconductor device according to claim 17, wherein
at least a part of the third electrode is between the first semiconductor portion and the second semiconductor portion in the second direction.

19. A method for manufacturing a wafer, comprising:
performing a first process on a first semiconductor layer including Alₓ₁Ga₁₋ₓ₁N (0≤x1<1) using a first source gas including Al, the first source gas being supplied at a first supply amount in the first process;
performing a second process after the first process, the first source gas being not used in the second process, or a second supply amount of the first source gas in the second process being smaller than the first supply amount; and
performing a third process using the first source gas and a second source gas to form a part of a second semiconductor layer after the second process, the second source gas including Ga, and the second semiconductor layer including Alₓ₂Ga₁₋ₓ₂N (x1<x2<1).

20. The method for manufacturing the wafer according to claim 19, wherein
a third supply amount of the first source gas in the third process is greater than the first supply amount.
